(19) United States
(12) Patent Application Publication
(10) Pub. No.: US 2014/0041707 A1
(43) Pub. Date: Feb. 13, 2014

(54) SOLAR BATTERY CELL, JUNCTION STRUCTURE, AND SOLAR BATTERY CELL FABRICATION METHOD

(71) Applicants: Hidetoshi Kitaura, Osaka (JP); Masaki Yoshida, Nara (JP)

(72) Inventors: Hidetoshi Kitaura, Osaka (JP); Masaki Yoshida, Nara (JP)

(73) Assignee: Panasonic Corporation, Kadoma-shi,Osaka (JP)

(21) Appl. No.: 14/113,229

(22) PCT Filed: Apr. 26, 2012
(86) PCT No.: PCT/JP2012/002862

§ 371 Date: Oct. 22, 2013

(30) Foreign Application Priority Data
Apr. 26, 2011 (JP) 2011-098157

(51) Int. Cl. H01L 31/05; H01L 31/18

(52) U.S. Cl. CPC H01L 31/0516; H01L 31/18
USPC 136/244; 438/98; 136/256

(57) ABSTRACT

Included are: a silicon substrate; a pair of finger electrodes connected to a P-type diffusion layer and an N-type diffusion layer respectively, which are formed in a first surface of the silicon substrate; an inner-part passivation layer that gives insulation between the pair of finger electrodes; a connecting area for connection with an outer part, in a gathering part where finger parts of one of the pair of finger electrodes gather; and a barrier part that is, within that connecting area, formed along tip ends of the finger parts of the other of the pair of finger electrodes, a polarity of the other being different from that of the one of the pair of finger electrodes of the connecting area.

### CROSS-REFERENCE TO RELATED APPLICATIONS

This application is a U.S. national phase application of PCT International Patent Application No. PCT/JP2012/002862 filed Apr. 26, 2012, claiming the benefit of priority of Japanese Patent Application No. 2011-098157 filed Apr. 26, 2011, all of which are incorporated by reference herein in their entirety.

### TECHNICAL FIELD

An aspect of the present invention is one that relates to a solar battery cell of the back-contact type, a joining structure body using solar battery cells and a manufacturing method of solar battery cells.

### BACKGROUND ART

For solar battery cells, many studies have been performed since old times with the aim of improvement of the electric-power-generation efficiency. Among various studies that are being performed even today for the purpose of electric-power-generation efficiency improvement of about zero point two or three percents, enlargement of the light-receiving square measure of a solar battery cell is a very effective means for the improvement of the electric-power-generation efficiency.

In order to enlarge the light-receiving square measure of the solar battery cell, disclosed is a solar battery cell of the back-contact type in which there is no electrode on the light-receiving surface by, in the solar battery cell that configures the solar battery, forming a P-type diffusion layer and an N-type diffusion layer in the non-light-receiving surface and providing electrodes (for example, see U.S. Pat. No. 5,053,083 and U.S. Pat. No. 4,927,770).

FIGS. 8(a)-(c) are figures that show a general solar battery cell of the back-contact type.

FIG. 8(a) is a schematic diagram that shows the light-receiving surface of the solar battery cell of the back-contact type. For the solar battery cell 600 of the back-contact type, the light-receiving surface 601 is provided on the face of the silicon substrate 602.

FIG. 8(b) is a schematic diagram that shows the non-light-receiving surface of the solar battery cell of the back-contact type. On the non-light-receiving surface 603 that is the reverse surface of the solar battery cell 600 of the back-contact type, the finger electrodes 604n and 604p, the cell-inner-part passivation layer 605 and the cell-outer-periphery passivation layer 606 are formed.

FIG. 8(c) is a figure that shows the L-L section of FIG. 8(b) of the solar battery cell of the back-contact type.

For the solar battery cell 600 of the back-contact type, the P-type diffusion layer 607 and the N-type diffusion layer 608 are formed in the non-light-receiving surface 603 of the silicon substrate 602. The P-type diffusion layer 607 and the N-type diffusion layer 608 are, in order to reduce recombination loss of carriers, alternately formed at constant intervals in the non-light-receiving surface 603 of the silicon substrate 602. Moreover, between the P-type diffusion layer 607 and the N-type diffusion layer 608, in order to keep the insulation, the cell-inner-part passivation layer 605 is formed. Further, in the end part of the outer periphery on the side of the non-light-receiving surface 603 of the silicon substrate 602, the cell-outer-periphery passivation layer 606 is formed. As for the cell-inner-part passivation layer 605 and the cell-outer-periphery passivation layer 606, SiO₂ or SiN with good insulation properties is used.

Further, on the diffusion layers 607 and 608 each, formed are the finger electrodes 604p and 604n for taking electricity out of the P-type diffusion layer 607 and the N-type diffusion layer 608 on the occasion of incidence of the sunlight from the light-receiving surface 601. As materials of the finger electrodes 604p and 604n, one kind or alternatively two or more kinds of Cu, Sn, Ag, Ni and the like with good electric conduction properties are used.

FIG. 9(a) is a schematic diagram that shows the details of the whole of the non-light-receiving surface 603 of the solar battery cell 600 of the back-contact type shown in FIG. 8(b).

On the non-light-receiving surface 603, in order to connect to an outer-part circuit or alternatively to another solar battery cell of the back-contact type, the positive-electrode solder-connecting pad 701 and the negative-electrode solder-connecting pad 702 are formed.

FIG. 9(b) is a figure that shows the vicinity of the positive-electrode solder-connecting pad 701, being surrounded with the broken line as the A region in FIG. 9(a). Below in FIG. 9(b), the vicinity of the negative-electrode solder-connecting pad 702 is specified that corresponds to the positive-electrode solder-connecting pad 701 located above.

The positive-electrode solder-connecting pad 701 is the broken-line region y being shown in FIG. 9(b) of the region where the finger electrodes 604p get together, and is the region that is surrounded by the finger electrodes 604n1-604n9, which gather in the negative-electrode solder-connecting pad 702 being shown in FIG. 9(a), and the cell-outer-periphery passivation layer 606. The positive-electrode solder-connecting pad 701 is the portion where the finger electrodes 604p get together as shown in FIG. 9(b), and is formed with one kind or alternatively two or more kinds of Cu, Sn, Ag, Ni and the like being used that are the same materials as those of the finger electrodes 604p and 604n.

FIG. 10 shows a figure of the connecting part of a joining structure body in which two sheets of the solar battery cells 600 of the back-contact type have been electrically connected.

For the two sheets of the solar battery cells 600 of the back-contact type, the positive-electrode solder-connecting pad 701 and the negative-electrode solder-connecting pad 702 are connected by the interconnector 801, using the solder 802. As a solder material, an SnAgCu system solder is used.

Describing connection of the two sheets of the solar battery cells 600 of the back-contact type, at the beginning, the solder 802 is supplied to both of the solder-connecting pads 701 and 702 with polarities different that have been formed on the solar battery cells 600. And, after the interconnector 801 has been mounted so as to span those solder-connecting pads 701 and 702, heating is carried out at the melting point of the solder 802 or more. By this heating the positive-electrode solder-connecting pad 701 and the negative-electrode solder-connecting pad 702 are allowed to be joined by the interconnector 801, using the solder 802, and it becomes possible to take out an objective electrical voltage and current.

FIG. 11 is a figure that has shown the connecting part of a joining structure body, in which two sheets of conventional solar battery cells of the back-contact type have been connected by a solder material using an interconnector, which has been specified in Japanese Patent Application Publication No. 2005-191479.

The joining structure body shown in FIG. 11 is one such that the solder 852 is supplied to the opposing positive-electrode solder-connecting pad 751 and negative-electrode solder-connecting pad 752 of the two sheets of the solar battery cells 650 of the back-contact type so that, with the interconnector 853 being mounted, heating and melting of the solder 852 and joining have been carried out.

By having allowed the configuration to be such that connection between the positive-electrode solder-connecting pad 751 and the negative-electrode solder-connecting pad 752 are plurally carried out with one sheet of the flat-board-like interconnector 853, connecting operation of the two sheets of the solar battery cells 650 of the back-contact type is allowed to be simple.

### SUMMARY OF THE INVENTION

### Problems to be Solved by the Invention

However, in the configuration of the conventional solar battery cell, because the portion of the solder-connecting pad for connection with the outer part by the solder needs to be formed with a wide square measure, the electric-power-generation efficiency has been lowered.

For example, also in the joining structure body specified in Japanese Patent Application Publication No. 2005-191479 being shown in FIG. 11, for the positive-electrode solder-connecting pad 751 and the negative-electrode solder-connecting pad 752, in order to allow them to join with the solder 852, metal materials of one kind or alternatively two or more kinds such as Cu, Sn, Ag, Ni and the like that easily get wet with the solder 852 can be used as formation materials of those. Because of that, on the occasion of joining with the solder 852 allowed to be heated and melted, the solder 852 wetly spreads on the positive-electrode solder-connecting pad 751 and on the negative-electrode solder-connecting pad 752. When the solder 852 wetly spreads across the cell-inner-part passivation layer 655 to get in contact with the finger electrodes 654n and 654p, the positive electrode and the negative electrode are short-circuited. Accordingly, in order to prevent a short circuit due to wetting spread of the solder 852, in consideration of the wetting spread of the solder 852, it has been necessary to design the positive-electrode solder-connecting pad 751 and the negative-electrode solder-connecting pad 752 so that their square measures are wide.

By allowing the square measures of the positive-electrode solder-connecting pad 751 and negative-electrode solder-connecting pad 752 to be wide, long becomes the moving distance of carriers from the P-type diffusion layer of the portion, which is in contact with the positive-electrode solder-connecting pad 751, to the N-type diffusion layer that is connected to the finger electrodes 654n and, moreover, long also becomes the moving distance of carriers from the N-type diffusion layer of the portion, which is in contact with the negative-electrode solder-connecting pad 752, to the P-type diffusion layer that is connected to the finger electrodes 654p. Because recombination loss of carriers increases accompanying that, the electric-power-generation efficiency has been lowered.

The present invention furnishes, in consideration of the abovenamed conventional problems, a solar battery cell, a joining structure body and a manufacturing method of solar battery cells such that the electric-power-generation efficiency is allowed to be improved.

### Means for Solving the Problem

In order to solve the above-stated problems, the 1^{st} aspect of the present invention is

a solar battery cell comprising:

a silicon substrate;

a pair of finger electrodes connected to a P-type diffusion layer and an N-type diffusion layer respectively, which are formed in a first surface of the silicon substrate;

an inner-part passivation layer that gives insulation between the pair of finger electrodes;

a connecting area for connection with an outer part, in a gathering part where finger parts of one of the pair of finger electrodes gather; and

a barrier part that is, within the connecting area, formed along tip ends of the finger parts of the other of the pair of finger electrodes, a polarity of the other being different from that of the one of the pair of finger electrodes of the connecting area.

Moreover, the 2^{nd} aspect of the present invention is

a solar battery cell according to the 1^{st} aspect of the present invention, wherein

the connecting areas are given to the pair of finger electrodes respectively.

Moreover, the 3^{rd} aspect of the present invention is

a solar battery cell according to the 1^{st} aspect of the present invention, wherein

the barrier part is in a circular-arc shape and, outside the circular-arc shape, the tip ends of the finger parts of the other of the pair of finger electrodes are arranged.

Moreover, the 4^{th} aspect of the present invention is

a solar battery cell according to the 1^{st} aspect of the present invention, wherein

the barrier part is formed with a material of at least one kind among a Si oxide, a Si nitride, a Ti oxide and a Ti nitride.

Moreover, the 5^{th} aspect of the present invention is

a joining structure body comprising a plurality of solar battery cells, each cell comprising: a silicon substrate; a pair of finger electrodes connected to a P-type diffusion layer and an N-type diffusion layer respectively, which are formed in a first surface of the silicon substrate; an inner-part passivation layer that gives insulation between the pair of finger electrodes; a connecting area for connection with an outer part, in a gathering part where finger parts of one of the pair of finger electrodes gather; and a barrier part that is, within the connecting area, formed along tip ends of the finger parts of the other of the pair of finger electrodes, a polarity of the other being different from that of the one of the pair of finger electrodes of the connecting area, with the connecting areas given to the pair of finger electrodes respectively, wherein

the solar battery cells are arranged so that the connecting areas with different polarities are opposing each other, and

for the adjoining solar battery cells, portions of the connecting areas that exist between the respective opposing barrier parts are linked via an interconnector that is connected with a solder.

Moreover, the 6^{th} aspect of the present invention is

a manufacturing method of a solar battery cell in which a pair of finger electrodes connected to a P-type diffusion layer and an N-type diffusion layer respectively are formed in a first surface of a silicon substrate, comprising:

a diffusion layer forming step of alternately disposing, in the first surface of the silicon substrate, the P-type diffusion layer and the N-type diffusion layer to form them in an interdigitated array shape respectively;

a passivation layer forming step of forming, after the diffusion layer forming step, in a connecting area for connection with an outer part in a gathering part where finger parts of at least one of the pair of finger electrodes gather, a barrier part along tip ends of the finger parts of the other of the pair of finger electrodes, a polarity of the other being different from that of the one of the pair of finger electrodes of the connecting area, on the first surface of the silicon substrate, together with an inner-part passivation layer for giving insulation between the pair of finger electrodes; and

an electrode forming step of allowing, after the passivation layer forming step, a metal to attach to a part of the first surface of the silicon substrate, in which part the inner-part passivation layer and the barrier part have not been formed, to form the pair of finger electrodes.

### Effects of the Invention

By the present invention, able to be furnished are a solar battery cell, a joining structure body and a manufacturing method of solar battery cells such that the electric-power-generation efficiency is allowed to be improved with the square measure of the solder-connecting pad being diminished.

### BRIEF DESCRIPTION OF THE DRAWINGS

FIG. 1(a) is a schematic top view, which shows the light-receiving surface of the solar battery cell in an embodiment of the present invention; and FIG. 1(b) is a schematic bottom view, which shows the non-light-receiving surface of the solar battery cell in an embodiment of the present invention.

FIG. 2 is a figure, which shows the positive-electrode solder-connecting pad vicinity and negative-electrode solder-connecting pad vicinity of the solar battery cell in an embodiment of the present invention.

FIGS. 3(a)-(d) are process drawings, for which the barrier parts are formed in an embodiment of the present invention.

FIG. 4 is a figure for which the square measure of the solder-connecting pad of the solar battery cell of an embodiment of the present invention, and the square measure of the solder-connecting pad of a conventional solar battery cell of the back-contact type are compared.

FIG. 5(a) is a figure that shows, when the interconnector has been connected to the positive-electrode solder-connecting pad of the solar battery cell, the positive-electrode solder-connecting pad vicinity in an embodiment of the present invention; and FIG. 5(b) is a figure that shows, when the interconnector has been connected to the positive-electrode solder-connecting pad of the conventional solar battery cell, the positive-electrode solder-connecting pad vicinity.

FIG. 6(a) is a figure which shows the positive-electrode solder-connecting pad vicinity of the solar battery cell of another configuration with the shape of the barrier part being different, in an embodiment of the present invention.

FIG. 6(b) is a figure which shows the positive-electrode solder-connecting pad vicinity of the solar battery cell of another configuration with the shape of the barrier part being different, in an embodiment of the present invention.

FIG. 6(c) is a figure which shows the positive-electrode solder-connecting pad vicinity of the solar battery cell of another configuration with the shape of the barrier part being different, in an embodiment of the present invention.

FIG. 7 is a section view of a solar battery cell in a case where the barrier parts have been formed after the solder-connecting pads have been formed, in an embodiment of the present invention.

FIG. 8(a) is a top view that shows the light-receiving surface of a conventional solar battery cell of the back-contact type; FIG. 8(b) is a bottom view that shows the non-light-receiving surface of the conventional solar battery cell of the back-contact type; and FIG. 8(c) is a section view of the conventional solar battery cell of the back-contact type.

FIG. 9(a) is a schematic diagram that shows the details of the non-light-receiving surface of the conventional solar battery cell of the back-contact type.

FIG. 9(b) is a schematic diagram that shows the positive-electrode solder-connecting pad vicinity and negative-electrode solder-connecting pad vicinity of the conventional solar battery cell of the back-contact type.

FIG. 10 is a figure that has shown the connecting part of a joining structure body in which two sheets of conventional solar battery cells of the back-contact type have been electrically connected.

FIG. 11 is a figure that has shown the connecting part of a joining structure body, in which two sheets of conventional solar battery cells of the back-contact type have been joined by a solder material with one sheet of the board-like interconnector.

### MODES FOR IMPLEMENTING THE INVENTION

In the following, descriptions are given regarding embodiments of the present invention referring to the drawings.

### Embodiment

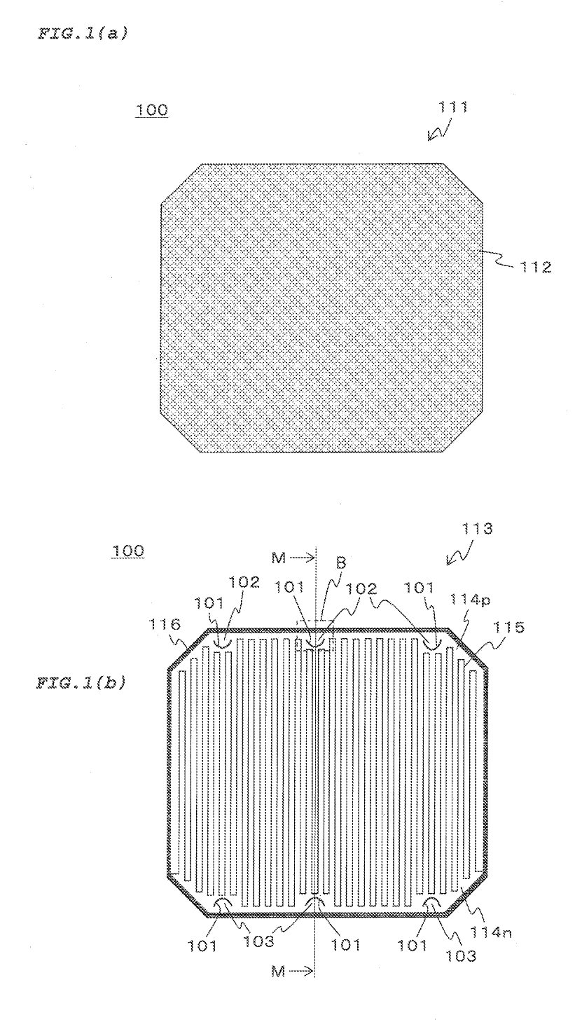

FIGS. 1(a) and (b) are a top view and a bottom view which have schematically shown the solar battery cell in an embodiment of the present invention, having barrier parts.

FIG. 1(a) is a top view that shows the light-receiving surface 111 of the solar battery cell of the back-contact type of the present embodiment.

The solar battery cell 100 of the present embodiment is configured with the silicon substrate 112, for the silicon substrate 112 the shape is octagonal, with the thickness of 0.2 mm, and the adjacent edges are 110.0 mm and 30.0 mm long with the edges facing each other being parallel. The size of the silicon substrate 112 originates with that of the silicon ingot, and the thickness and largeness of the silicon substrate 112 are not limited to the abovenamed size.

FIG. 1(b) is a bottom view that shows the non-light-receiving surface 113 of the solar battery cell 100 of the present embodiment.

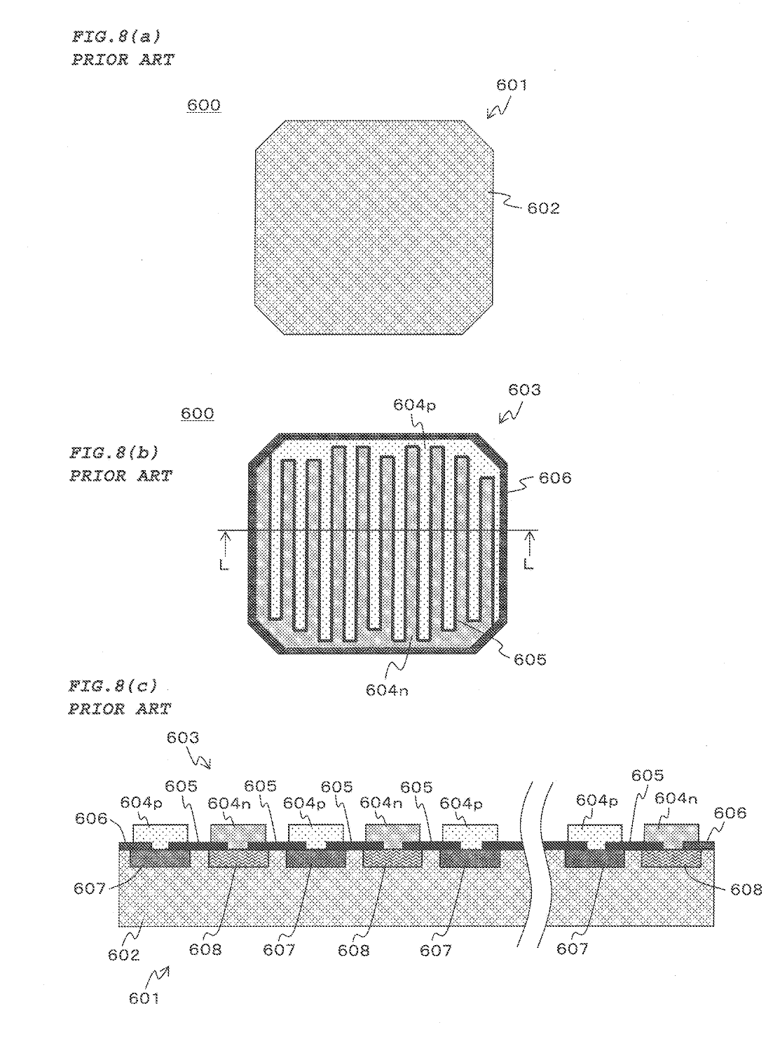

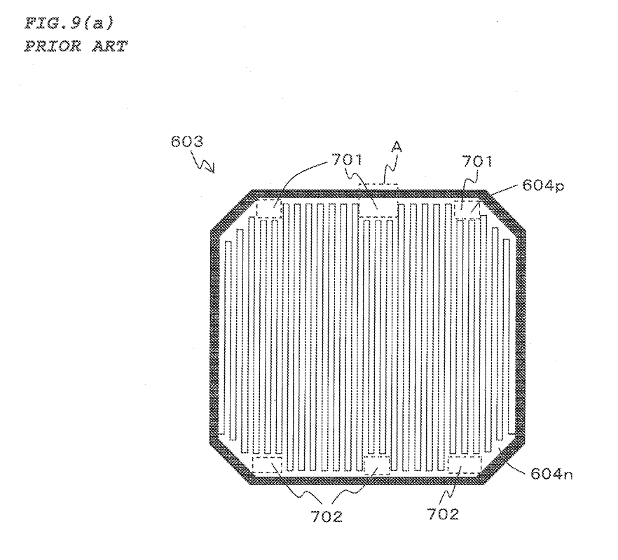

On the non-light-receiving surface 113, the positive-electrode solder-connecting pad 102 and the negative-electrode solder-connecting pad 103 are formed, each at three places, so as to oppose the insides of the opposite edges being the long edges of the solar battery cell 100. Moreover, the finger electrodes 114p that get together in the positive-electrode solder-connecting pad 102 and the finger electrodes 114n that get together in the negative-electrode solder-connecting pad are formed in interdigitated array shaping (for the figure of the interdigitated array shaping, see FIG. 8(b)), and between the finger electrodes 114p and 114n, the cell-inner-part passivation layer 115 as an insulating layer is formed. Moreover, in the respective solder-connecting pads 102 and 103, the barrier parts 101 are formed.

Additionally, the non-light-receiving surface 113 serves as one example of the first surface of the silicon substrate of the present invention. Moreover, the finger electrodes 114p and 114n serve as one example of the pair of finger electrodes of the present invention. Moreover, the positive-electrode solder-connecting pad 102 and the negative-electrode solder-connecting pad 103 both serve as one example of the connecting area of the present invention for connection with an outer part. Moreover, the portion where the finger electrodes 114p gather, namely the portion of the finger electrode 114p along the upper edge in the solar battery cell 100 of FIG. 1(b) serves as one example of the gathering part of the present invention, and the portion not divided by the cell-inner-part passivation layer 115, where the finger electrodes 114n gather, namely the portion of the finger electrode 114n along the lower edge in the solar battery cell 100 of FIG. 1(b) also serves as one example of the gathering part of the present invention. Moreover, the cell-inner-part passivation layer 115 serves as one example of the inner-part passivation layer of the present invention.

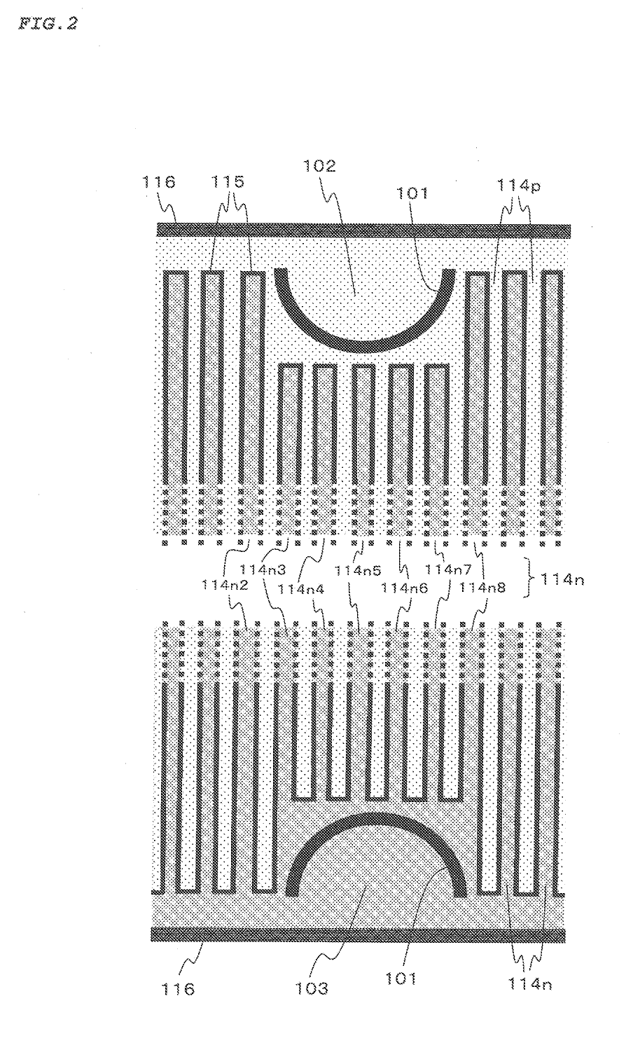

FIG. 2 is an enlarged view of the vicinity of the positive-electrode solder-connecting pad 102 of the present embodiment, being surrounded with the broken line as the B region in FIG. 1(b). Below in FIG. 1(b), the vicinity of the negative-electrode solder-connecting pad 103 is specified that corresponds to the positive-electrode solder-connecting pad 102 located above.

The barrier part 101 that is formed in the positive-electrode solder-connecting pad 102 is, along the tip end portions of the finger electrodes 114n2, 114n3, 114n4, 114n5, 114n6, 114n7 and 114n8 each that form the finger electrode 114n, formed in a circular-arc shape that is opened towards the cell-outer-periphery passivation layer 116. In this FIG. 2, the tip end portions of the finger electrodes 114n3-114n7 are depicted in alignment, but the tip end portions of the finger electrodes 114n3, 114n4, 114n6 and 114n7 may be formed so as to get close to the barrier part 101.

The cell-inner-part passivation layer 115 is, since being provided in order to keep the insulation between the finger electrode 114p formed on the P-type diffusion layer 117 and the finger electrode 114n formed on the N-type diffusion layer 118, formed with an oxide and a nitride such as SiO₂, SiN, TiO, TiO₂ and the like that are insulating materials. For these oxides and nitrides, wetting properties with solders are bad. The wetting spread of the solder within the positive-electrode solder-connecting pad 102 is able to be suppressed by the barrier part 101, by forming the barrier part 101 within the positive-electrode solder-connecting pad 102, on the occasion of formation of the cell-inner-part passivation layer 115, together with the cell-inner-part passivation layer 115, with the materials with which the cell-inner-part passivation layer 115 is formed. Namely, the barrier part 101 is formed using a material of at least one kind out of an oxide and a nitride such as SiO₂, SiN, TiO, TiO₂ and the like that are insulating materials

Next, descriptions are given regarding the forming method of the barrier part 101 in the present embodiment.

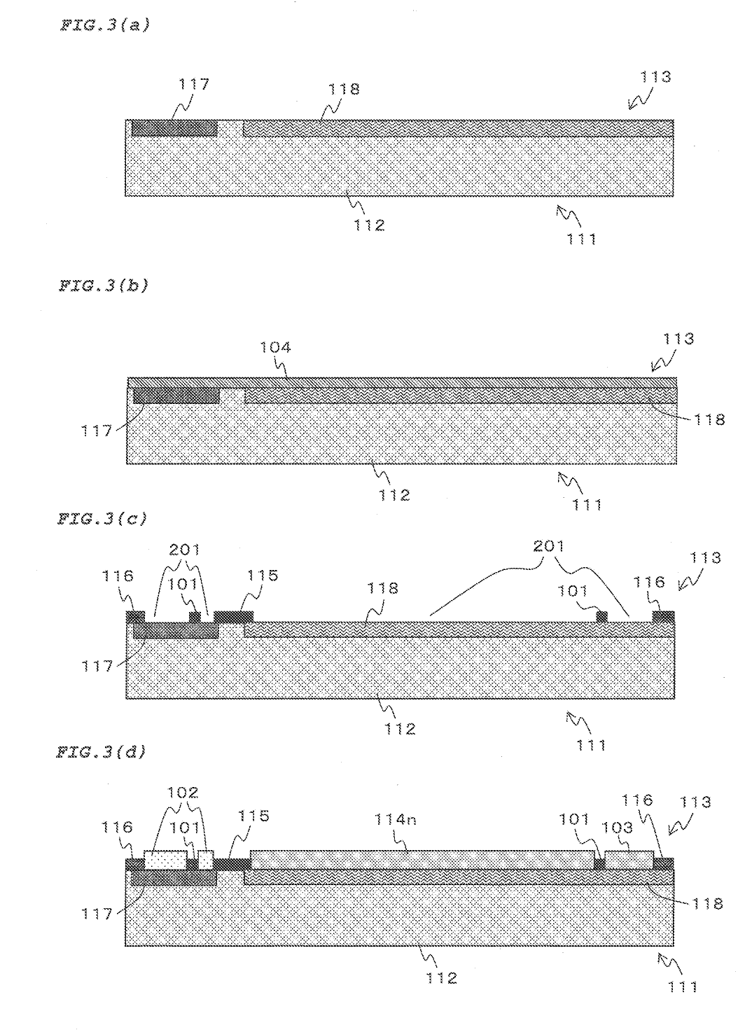

FIGS. 3(a)-(d) are process drawings for which the barrier parts 101 are formed. FIGS. 3(a)-(d) show the respective processes, and show section views of the M-M section of FIG. 1(b).

FIG. 3(a) is a figure for which the P-type diffusion layer 117 and the N-type diffusion layer 118 have been formed in the silicon substrate 112.

Masking is applied on the non-light-receiving surface 113 of the silicon substrate 112, the P-type diffusion layer 117 is formed, the mask pattern is next altered, and the N-type diffusion layer 118 is formed.

FIG. 3(b) is a figure of the process of forming the passivation layer.

The passivation layer 104 is, so as to cover the silicon substrate 112, and the P-type diffusion layer 117 and N-type diffusion layer 118 formed in the silicon substrate 112, formed on the whole surface of the non-light-receiving surface 113.

FIG. 3(c) is a figure of the process of forming the contact holes.

By partly removing the passivation layer 104 formed in the process being shown in FIG. 3(b), formed are the contact holes 201 of the passivation layer 104 such that the object is to form electrical connecting places in the P-type diffusion layer 117 and the N-type diffusion layer 118. As a forming method of the contact holes 201 of the passivation layer 104, masking is applied on the passivation layer 104 on the side of the non-light-receiving surface 113, and dry or alternatively wet etching is performed. By this, the contact holes 201 are able to be formed from which the P-type diffusion layer 117 and the N-type diffusion layer 118 are exposed. Moreover, the places of the passivation layer 104 shown in FIG. 3(b) where the etching is not performed remain as the cell-outer-periphery passivation layer 116, the cell-inner-part passivation layer 115 and the barrier parts 101.

FIG. 3(d) is a figure for which the finger electrodes 114p and 114n, and the solder-connecting pads 102 and 103 have been allowed to connect to the P-type diffusion layer 117 and the N-type diffusion layer 118.

To the contact holes 201 from which the P-type diffusion layer 117 and N-type diffusion layer 118 formed in the non-light-receiving surface 113 of the silicon substrate 112 are exposed, electro-Cu plating is performed, and the positive-electrode solder-connecting pad 102, the finger electrodes 114p and 114n and the negative-electrode solder-connecting pad 103 are formed. Because, in the electro-Cu plating, plating is not formed on the cell-outer-periphery passivation layer 116, the cell-inner-part passivation layer 115 and the barrier parts 101 that are insulating layers, these portions that have been formed with the passivation layer 104 are exposed.

By this process, the barrier parts 101 are able to be formed in the positive-electrode solder-connecting pad 102 on the side of the finger electrode 114n, which opposes the cell-outer-periphery passivation layer 116, and, the negative-electrode solder-connecting pad 103 on the side of the finger electrode 114p, which opposes the cell-outer-periphery passivation layer 116.

Additionally, the process shown in FIG. 3(a) serves as one example of the diffusion layer forming step of the present invention. Moreover, the process shown in FIGS. 3(b) and (c) serves as one example of the passivation layer forming step of the present invention. Moreover, the process shown in FIG. 3(d) serves as one example of the electrode forming step of the present invention.

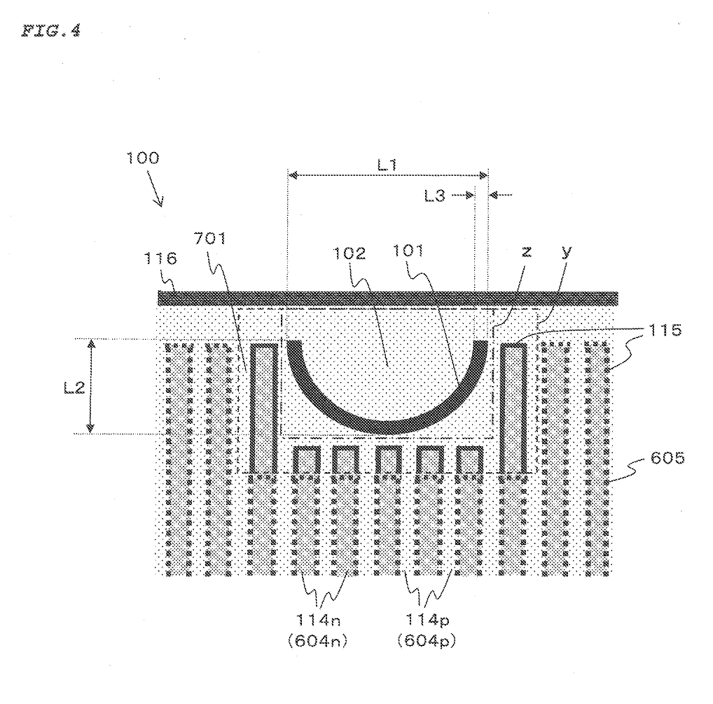

FIG. 4 is a figure for which the square measure of the solder-connecting pad of the solar battery cell of the present embodiment, and the square measure of the solder-connecting pad in a conventional solar battery cell of the back-contact type are compared, and shows a portion of the positive-electrode solder-connecting pad.

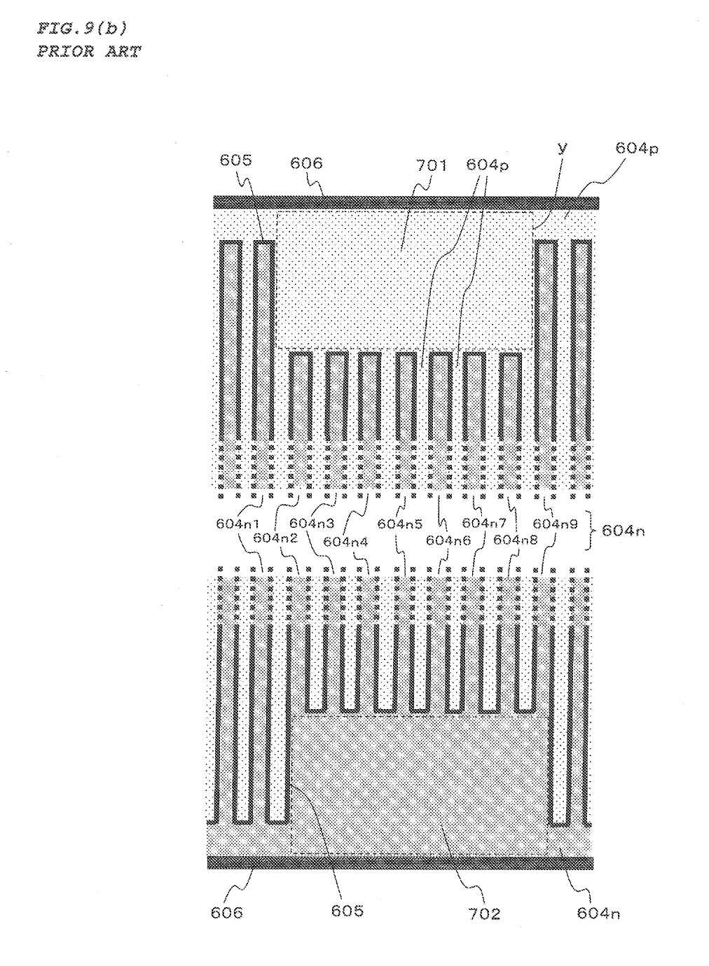

In the cell-inner-part passivation layer 115 of the place that covers the finger electrode 114n in the solar battery cell 100 of the present embodiment, shown with the solid lines are the portions that have increased, compared with the conventional solar battery cell 600 being shown in FIGS. 8-10. Moreover, in the cell-inner-part passivation layer 115 of the solar battery cell 100 of the back-contact type of the present embodiment, shown with the dotted lines are the same places as those of the conventional solar battery cell 600.

3.5 mm×3.5 mm wide is the region z (the region surrounded with the dot and dash line of FIG. 4) of the positive-electrode solder-connecting pad 102, which has the barrier part 101, of the solar battery cell 100 of the present embodiment and, because 10.0 mm×10.0 mm wide is the region y (the region surrounded with the broken line of FIG. 4) of the conventional positive-electrode solder-connecting pad 701, apparently the square measure of the region z of the positive-electrode solder-connecting pad 102 of the present embodiment is decreased that has the barrier part 101.

Like this, 22326.9 mm² is the square measure of the solar battery cell 100 of the present embodiment with the largeness of the barrier part 101 allowed to be L1:3.2 mm, L2:2.5 mm and L3:0.5 mm, in which the barrier part 101 in circular-arc shaping is formed that is open to the side of the cell-outer-periphery passivation layer 116 along the tip ends of the finger electrodes 114n, 73.5 mm² is the total square measure of six places of the positive-electrode solder-connecting pad 102 and the negative-electrode solder-connecting pad 103, each being provided at three places respectively, and 17788.0 mm² is the total square measure of the finger electrodes 114p and 114n. On the other hand, in the case where, with the conventional solar battery cell 600 in which the barrier parts 101 are not formed, the square measure of the solar battery cell is similar to the square measure of the solar battery cell 100 of the present embodiment, 600 mm² is the total square measure of six places of the positive-electrode solder-connecting pad 701 and the negative-electrode solder-connecting pad 702, each being provided at three places respectively, and 17261.5 mm² is the total square measure of the finger electrodes 604p and 604n.

Comparing the square measures of the finger electrodes of the solar battery cell 100 of the present embodiment and the conventional solar battery cell 600 it is possible, with the solar battery cell 100 of the present embodiment, to enlarge the square measure of the finger electrode by 3%. Performed is the square-measure cutting-down of the P-type diffusion layer 607, which comes in contact with the positive-electrode solder-connecting pad 701, by the cutting-down of the square measure of the positive-electrode solder-connecting pad 701, to form, at the place of that square measure cut down, the N-type diffusion layer 118 and the finger electrode 114n connected to that N-type diffusion layer 118 and, moreover, performed is the square-measure cutting-down of the N-type diffusion layer 608, which comes in contact with the negative-electrode solder-connecting pad 702, by the cutting-down of the square measure of the negative-electrode solder-connecting pad 702, to form, at the place of that square measure cut down, the P-type diffusion layer 117 and the finger electrode 114p connected to that P-type diffusion layer 117, so that it is thereby possible to reduce, with the moving distance of carriers able to be shortened, recombination loss of carriers.

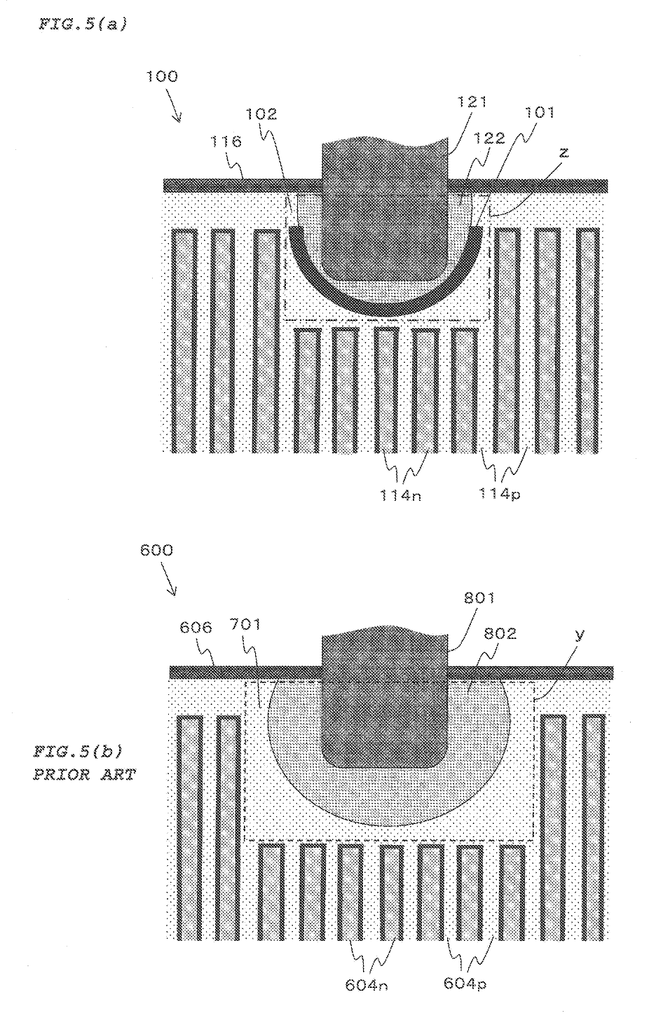

FIG. 5(a) is a figure that shows the vicinity of the positive-electrode solder-connecting pad 102 of the joining structure body, in which the interconnector has been connected to the positive-electrode solder-connecting pad 102 of the solar battery cell, in the present embodiment.

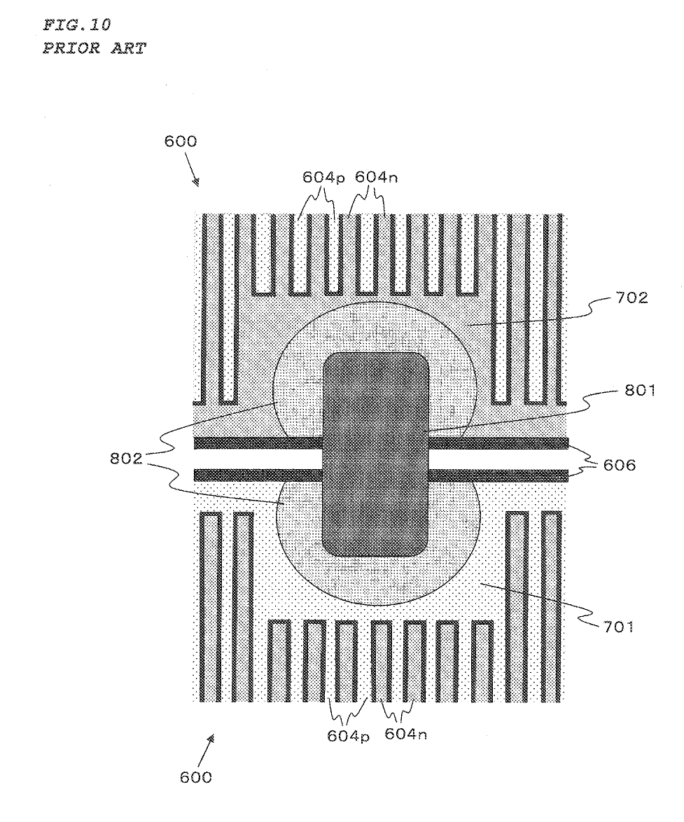

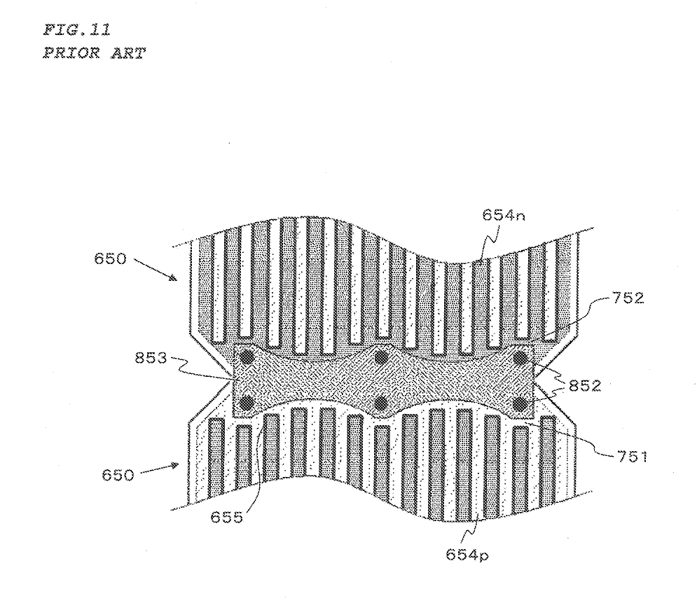

The interconnector 121 used in the present embodiment is one that is the same as the interconnector 801 used on the occasion of joining the conventional solar battery cells 600 shown in FIG. 10.

On the occasion of connection of the solar battery cell 100 of the present embodiment and the interconnector 121 using the solder 122, the barrier part 101 in circular-arc shaping open to the side of the cell-outer-periphery passivation layer 116, which has been formed with the same materials as those of the cell-inner-part passivation layer 115, has been provided within the positive-electrode solder-connecting pad 102, which is the z region shown in FIG. 5(a), along the tip ends of the finger electrodes 114n, wetting spread at the time of solder melting is thereby able to be suppressed. By enabling the wetting spread at the time of solder melting to be suppressed, the square measure of the P-type diffusion layer 607, which has been in contact with the conventional positive-electrode solder-connecting pad 701, is able to be cut down to form, at the place of that square measure cut down, the N-type diffusion layer 118 of the present embodiment and the finger electrode 114n connected to that N-type diffusion layer 118 and, moreover, the square measure of the N-type diffusion layer 608, which has been in contact with the conventional negative-electrode solder-connecting pad 702, is also able to be cut down to form, at the place of that square measure cut down, the P-type diffusion layer 117 of the present embodiment and the finger electrode 114p connected to that P-type diffusion layer 117, so that the electric-power-generation efficiency of the solar battery cell of the back-contact type is thereby able to be improved.

FIG. 5(b) is a figure that shows the vicinity of the positive-electrode solder-connecting pad 701 of the joining structure body, in which the interconnector has been connected to the positive-electrode solder-connecting pad 701 of the conventional solar battery cell 600.

On the occasion of connection of the solar battery cell 600 and the interconnector 801 using the solder 802, in the positive-electrode solder-connecting pad 701, which is the y region shown in FIG. 5(b), the solder 802 wetly spreads. For the positive-electrode solder-connecting pad 701, because a wetting property with the solder 802 is formed by Cu, the solder 802 wetly spreads when the solder 802 is allowed to be heated and melted at the time of connection.

From this result, the solar battery cell 100 of the present embodiment that has the barrier parts 101 is apparently able to suppress wetting spread of the solder, and it is possible to prevent a short circuit of the finger electrodes.

Table 1 shows the results of the difference in the solder amount and the effect of the width (see L3 of FIG. 4) of the barrier part 101, verified using the solar battery cell 100 of the configuration of the present embodiment.

On the occasion of connection of the solder-connecting pads 102 and 103 of the solar battery cells 100 of the back-contact type and the interconnector 121 with the solder 122 allowed to be melted, existence and nonexistence of a short circuit between the finger electrodes 114p and 114n due to the difference in the width of the barrier part 101 has been confirmed. O shows the case of nonexistence of a short circuit, and X the case of existence of a short circuit.

TABLE 1

Solder amount (mg)

| | | 1 | 5 | 10 | 20 |
|---|---|---|---|---|---|
| Barrier | 0.1 | X | X | X | X |
| part | 0.2 | ◯ | X | X | X |
| width | 0.5 | ◯ | ◯ | ◯ | ◯ |
| (mm) | 0.7 | ◯ | ◯ | ◯ | ◯ |

In the case where the width of the barrier part 101 being exposed is 0.1 mm, even with the solder amount of 1 mg, the solder wetly spreads across the barrier part 101 and wetting spread of the solder was not able to be suppressed. On the other hand, with the width of the barrier part 101 of 0.2 mm, wetting spread is able to be suppressed in the case where the solder amounts to 1 mg, but wetting spread was not able to be suppressed with the solder amounting to 5 mg. Yet, in the cases where the width of the barrier part 101 is 0.5 mm or more, even with the solder amount becoming 20 mg, it was possible to suppress wetting spread of the solder.

From these results, the joining structure body in which the solar battery cells 100 of the present embodiment, which have the barrier parts 101, have been joined with the interconnector using the solder, compared with the joining structure body, in which the conventional solar battery cells 600 have been joined with the interconnector using the solder, is able to suppress wetting spread of the solder by the barrier parts 101, and it is possible to prevent a short circuit of the finger electrodes due to the solder connection.

Additionally, in the above-named embodiments, the descriptions have been given for the examples on which the shape of the barrier part 101 is allowed to be in circular-arc shaping that is open to the side of the cell-outer-periphery passivation layer 116, but similar effects are obtained even with another shape, being a concave shape that is open to the side of the cell-outer-periphery passivation layer 116.

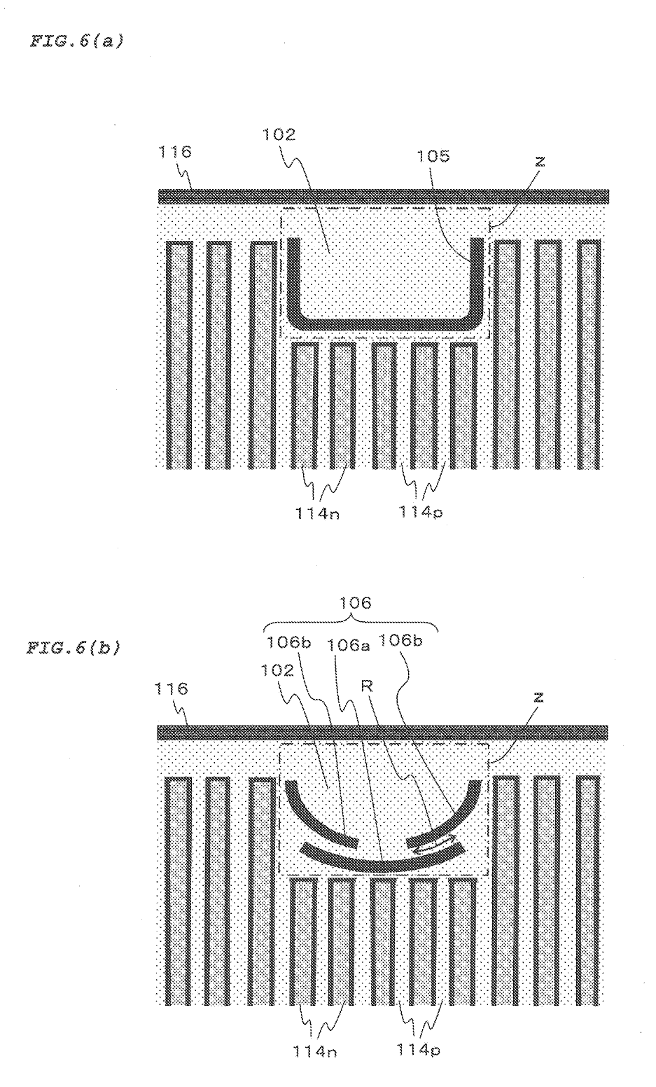

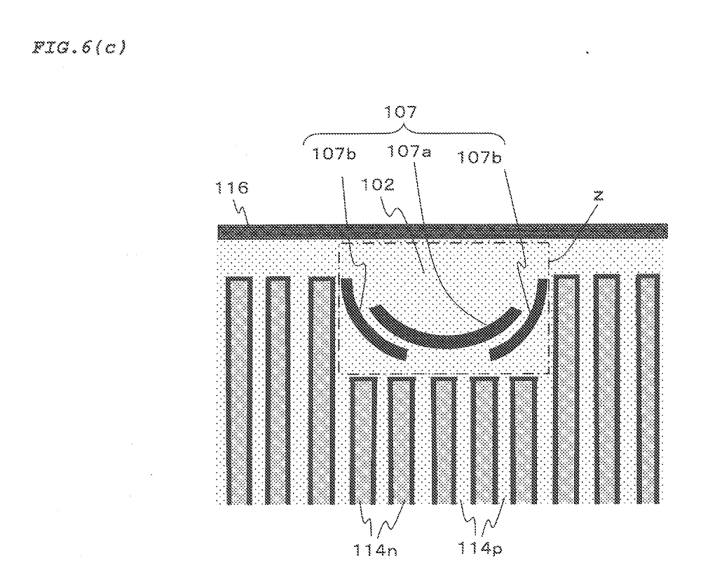

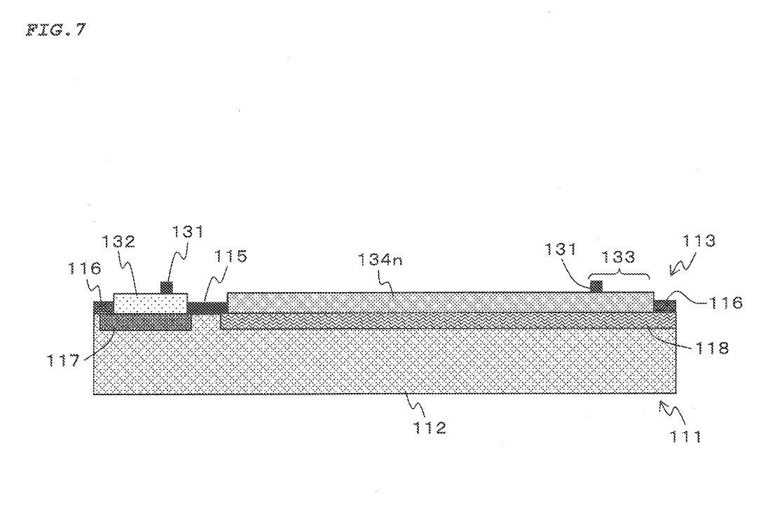

In FIGS. 6(a) and (b), figures of the vicinities of the positive-electrode solder-connecting pads of solar battery cells of other configurations of the present embodiment, with the barrier parts allowed to be in other shapes. Additionally, for the same configuration portions as those in FIG. 2, the same reference numerals are used.

Effects similar to those of the barrier part 101 are obtained, with any shape that encloses the interconnector 121, which is connected, and has a space between the interconnector 121 and itself, like the barrier part 105 shown in FIG. 6(a) and the barrier part 106 shown in FIG. 6(b).

Moreover, the shape of the barrier part may be allowed to be one contiguous shape like the barrier part 101 of FIG. 2 or the barrier part 105 of FIG. 6(a), and may be, like the barrier part 106 of FIG. 6(b), configured with plural shapes in combination. The barrier part 106 shown in FIG. 6(b) is allowed to be partitioned into three portions, and has the central portion 106a, and the portions 106b that are arranged on its right and left. This central portion 106a is arranged inside, and the right and left portions 106b outside.

In a case where a configuration has been given with plural shapes in combination like the barrier part 106 of FIG. 6(b), in comparison with the barrier part 101 and the barrier part 105, enabled to be less are the portions where the connection gets discontinuous in the positive-electrode solder-connecting pad 102 between the inside and outside of the barrier part 106, which becomes advantageous in respect of the connection resistance between the positive-electrode solder-connecting pad 102 and the other portion of the finger electrode 114p.

Moreover, in the case of the configuration shown in FIG. 6(b), there is a portion where the positive-electrode solder-connecting pad 102 is continuous on the inside and outside of the barrier part 106, but wetting spread of the solder toward the outside is able to be suppressed by allowing the channel (see the arrow R of FIG. 6(b)), which leads from the inside of the barrier part 106 to the outside, to be long like the barrier part 106.

Additionally, in FIG. 6(b), the barrier part 106 with the central portion being arranged outside the right-and-left portions is used but, as shown in FIG. 6(c), the barrier part 107 with the central portion 107a being arranged inside the right and left portions 107b may be used.

Moreover, the barrier parts 106 and 107 may be configured so as to be partitioned into four or more portions, and arranged alternately inside and outside.

Moreover, in the above-named present embodiment, as has been described using FIG. 3, the descriptions have been given for the examples on which, before the positive-electrode solder-connecting pad 102 and the negative-electrode solder-connecting pad 103 are formed, on the occasion of formation of the cell-inner-part passivation layer 115 and the cell-outer-periphery passivation layer 116, the barrier parts 101 are formed at the same time, but the barrier parts may be allowed to be formed after the positive-electrode solder-connecting pad 102 and the negative-electrode solder-connecting pad 103 have been formed.

In FIG. 7 shown is a section view of a solar battery cell in a case where, after the solder-connecting pads have been formed, the barrier parts have been formed. The section being shown in FIG. 7 shows a section of the portion that corresponds to the M-M section of FIG. 1(b). Additionally, for the same configuration portions as those in FIG. 3(d), the same reference numerals are used.

Since the barrier parts are formed after the process, for which the descriptions have been given with FIG. 3(d), of forming the finger electrode 134n, the positive-electrode solder-connecting pad 132 and the negative-electrode solder-connecting pad 133, as shown in FIG. 7, the barrier parts 131 are formed on the positive-electrode solder-connecting pad 132 and the negative-electrode solder-connecting pad 133.

The barrier parts 131 may be, for example, formed with the same materials as those of the cell-inner-part passivation layer 115 and the cell-outer-periphery passivation layer 116, and a tape the face of which is formed with these materials may be allowed to be stuck on the positive-electrode solder-connecting pad 132 and the negative-electrode solder-connecting pad 133.

In the case of the configuration shown in FIG. 7, in the positive-electrode solder-connecting pad 132 and the negative-electrode solder-connecting pad 133, there is no disconnected portion inside and outside the barrier part 131, which is therefore advantageous in respect of the connection resistance between the solder-connecting pad and the finger electrode (for example, between the finger electrode 134n and the other portion of the negative-electrode solder-connecting pad 133). Moreover, the height of the barrier part 131 to form is able to be changed, and also the barrier part 131 is enabled to be high. By allowing the barrier part 131 to be high, it is also possible to allow the width (L3 of FIG. 4) of the barrier part 131 to be narrow.

Moreover, regarding the position where the solder-connecting pad is provided with the barrier part, according to the joining strength and the largeness of the interconnector, it is also possible to carry out an appropriate adjustment.

As has been described above, the solar battery cell of the present embodiment is, by having provided the solder-connecting pads with the barrier parts, able to suppress wetting spread of the solder in the solder-connecting pads, and a short circuit of the finger electrodes due to the solder is able to be prevented. And, able to be cut down are the square measures of the positive-electrode and negative-electrode solder-connecting pads and the P-type and N-type diffusion layers that are in contact with those solder-connecting pads and, since at the places with those square measures cut down able to be formed are the P-type diffusion layer and the finger electrode connected to that P-type diffusion layer, and the N-type diffusion layer and the finger electrode connected to that N-type diffusion layer, the electric-power-generation efficiency of the solar battery cell of the back-contact type is enabled to be improved.

Like this, it is possible for the solar battery cell of the present invention to allow the electric-power-generation efficiency of the solar battery cell of the back-contact type to be improved, being applicable to a module of the solar battery.

### INDUSTRIAL APPLICABILITY

A solar battery cell, a joining structure body and a manufacturing method of solar battery cells pertaining to the present invention have an effect of allowing the electric-power-generation efficiency to be improved with the square measure of the solder-connecting pad being diminished, and are useful for a solar battery cell of the back-contact type, a joining structure body using solar battery cells, a manufacturing method of solar battery cells and the like.

### DESCRIPTION OF THE REFERENCE NUMERALS

100 solar battery cell

101 barrier part

102 positive-electrode solder-connecting pad

103 negative-electrode solder-connecting pad

104 passivation layer

105 barrier part

106 barrier part

111 light-receiving surface

112 silicon substrate

113 non-light-receiving surface

114n, 114p, 114n2-114n8 finger electrode

115 cell-inner-part passivation layer

116 cell-outer-periphery passivation layer

117 P-type diffusion layer

118 N-type diffusion layer

121 interconnector

122 solder

131 barrier part

132 positive-electrode solder-connecting pad

133 negative-electrode solder-connecting pad

134n finger electrode

201 contact hole

600, 650 solar battery cell

601 light-receiving surface

602 silicon substrate

603 non-light-receiving surface

604n, 604p, 604n1-604n9, 654n, 654p finger electrode

605, 655 cell-inner-part passivation layer

606 cell-outer-periphery passivation layer

607 P-type diffusion layer

608 N-type diffusion layer

701, 751 positive-electrode solder-connecting pad

702, 752 negative-electrode solder-connecting pad

801 interconnector

802, 852 solder

803, 853 interconnector

1. A solar battery cell comprising:
a silicon substrate;
a pair of finger electrodes connected to a P-type diffusion layer and an N-type diffusion layer respectively, which are formed in a first surface of the silicon substrate;
an inner-part passivation layer that gives insulation between the pair of finger electrodes;
a connecting area for connection with an outer part, in a gathering part where finger parts of one of the pair of finger electrodes gather; and
a barrier part that is, within the connecting area, formed along tip ends of the finger parts of the other of the pair of finger electrodes, a polarity of the other being different from that of the one of the pair of finger electrodes of the connecting area.

2. A solar battery cell according to claim 1, wherein
the connecting areas are given to the pair of finger electrodes respectively.

3. A solar battery cell according to claim 1, wherein
the barrier part is in a circular-arc shape and, outside the circular-arc shape, the tip ends of the finger parts of the other of the pair of finger electrodes are arranged.

4. A solar battery cell according to claim 1, wherein
the barrier part is formed with a material of at least one kind among a Si oxide, a Si nitride, a Ti oxide and a Ti nitride.

5. A joining structure body comprising a plurality of solar battery cells, each cell comprising: a silicon substrate; a pair of finger electrodes connected to a P-type diffusion layer and an N-type diffusion layer respectively, which are formed in a first surface of the silicon substrate; an inner-part passivation layer that gives insulation between the pair of finger electrodes; a connecting area for connection with an outer part, in a gathering part where finger parts of one of the pair of finger electrodes gather; and a barrier part that is within the connecting area, formed along tip ends of the finger parts of the other of the pair of finger electrodes, a polarity of the other being different from that of the one of the pair of finger electrodes of the connecting area, with the connecting areas given to the pair of finger electrodes respectively, wherein
the solar battery cells are arranged so that the connecting areas with different polarities are opposing each other, and
for the adjoining solar battery cells, portions of the connecting areas that exist between the respective opposing barrier parts are linked via an interconnector that is connected with a solder.

6. A manufacturing method of a solar battery cell in which a pair of finger electrodes connected to a P-type diffusion layer and an N-type diffusion layer respectively are formed in a first surface of a silicon substrate, comprising:
a diffusion layer forming step of alternately disposing, in the first surface of the silicon substrate, the P-type diffusion layer and the N-type diffusion layer to form them in an interdigitated array shape respectively;
a passivation layer forming step of forming, after the diffusion layer forming step, in a connecting area for connection with an outer part in a gathering part where finger parts of at least one of the pair of finger electrodes gather, a barrier part along tip ends of the finger parts of the other of the pair of finger electrodes, a polarity of the other being different from that of the one of the pair of finger electrodes of the connecting area, on the first surface of the silicon substrate, together with an inner-part passivation layer for giving insulation between the pair of finger electrodes; and
an electrode forming step of allowing, after the passivation layer forming step, a metal to attach to a part of the first surface of the silicon substrate, in which part the inner-part passivation layer and the barrier part have not been formed, to form the pair of finger electrodes.
